(19) United States
(12) Patent Application Publication
(10) Pub. No.: US 2024/0255843 A1
(43) Pub. Date: Aug. 1, 2024

(54) METHOD FOR EXAMINING SAMPLES PERTAINING TO MICROLITHOGRAPHY

(71) Applicant: Carl Zeiss SMT GmbH, Oberkochen (DE)

(72) Inventor: Thomas Witkowski, Oberkochen (DE)

(21) Appl. No.: 18/422,302

(22) Filed: Jan. 25, 2024

(30) Foreign Application Priority Data
Feb. 1, 2023 (DE) 102023102475.2

(51) Int. Cl. G03F 1/84

(52) U.S. Cl. CPC G03F 1/84

(57) ABSTRACT

Disclosed is a method for examining samples pertaining to microlithography, comprising the following steps:
generating an aerial image of at least one considered region of the sample and generating image structures from the aerial image,
determining distances between a plurality of starting structures present in the aerial image and respective neighboring structures, determining the distances being effected by firstly determining intersection structures intersected by a predetermined intersection line proceeding to from the respective starting structure; in this case, rectangle structures are defined in the considered region for the determination of the intersection structures.

### CROSS-REFERENCE TO RELATED APPLICATIONS

The present patent application claims priority from German patent application DE 10 2023 102 475.2, filed on Feb. 1, 2023, the content of which is fully incorporated by reference herein.

### TECHNICAL FIELD

This disclosure relates to a method for examining samples pertaining to microlithography, for example photomasks or else other samples, for example exposed wafers or the like.

### BACKGROUND

Such methods often involve carrying out evaluations along lines—so-called slices—in an aerial image recorded by a recording device.

In this regard, for example, the published German patent application DE 10 2019 218 517 A1, attributed to the applicant, presents a method in which the image of a photomask to be measured is evaluated along a so-called comparison line. Along this comparison line, the quality of the examined mask can be deduced on the basis of, for example, an evaluation of an intensity profile along the comparison line and a comparison of a corresponding evaluation with respect to a reference image that is available or simulated. According to the teaching of the cited document, the comparison line is oriented in such a way that it intersects structures of interest or their edge boundaries as far as possible at a right angle in order to increase the accuracy in the determination of the position of the corresponding intersection points.

Furthermore, there is often interest in determining distances between individual structures in the context of so-called critical dimension (CD) measurements. Measurements of this type are required for example for predicting possible fault or leakage currents in a semiconductor circuit to be fabricated. Slices are likewise used for determining the distances. Complex computations leading to long computation times are often required here for determining neighboring structures and the distances thereof.

### SUMMARY

In certain aspects, an object of the present disclosure is to specify a method which enables the computation times incurred to be shortened.

For example, a method for examining samples pertaining to microlithography comprises the following steps: i) an aerial image of at least one considered region of the sample is generated; ii) subsequently, image structures are generated from the aerial image. In this case, a sample for microlithography may be understood to mean a wide variety of objects which are of interest for imaging examinations. In particular, masks or wafers are appropriate here.

Image structures are graphical structures which are generated from the aerial image and which represent real objects, for example the structures on the mask that are required for producing contact holes. In this regard, for example, the image structures may be polygons which were generated from the edge contours of the corresponding mask structures.

Determining distances between a plurality of starting structures present in the aerial image and respective neighboring structures is effected by firstly determining intersection structures intersected by a predetermined intersection line—the slice—proceeding from the respective starting structure.

In this case, a starting structure should be understood to mean an image structure from which an intersection line proceeds. In this case, the intersection line is usually perpendicular to that section of the starting structure from which it proceeds. Upon application of the method, multiple, usually all, image structures are successively used as starting structures.

According to certain embodiments disclosed herein, the determination of the intersection structures is considerably simplified and thus accelerated by rectangle structures being defined in the considered region for the determination of the intersection structures.

In a first, simple embodiment, rectangle structures can be created in this case by a respective rectangle structure containing exactly one image structure. In particular, rectangle structures can be created as minimal boxes by rectangles being circumscribed around image structures. In other words, in this case, the polygonal image structures obtained from the aerial image are replaced by rectangles containing the corresponding image structures. Optimally, the rectangles are chosen to be as small as possible for this purpose.

The use of rectangle structures in this case has the advantage that an intersection of a line (of the slice) with a rectangle can be determined significantly more easily and thus more rapidly than an intersection with a more complex polygon. In this way, a simple prior check can be made to establish whether, for the respective rectangle structure, an intersection with the image structure contained therein is appropriate in the first place.

In further embodiments, a further acceleration of the method can alternatively or additionally be achieved by rectangle structures being created as index rectangles by rectangular regions being defined in the considered region, which rectangular regions contain a plurality of minimal boxes or image structures indexed on the basis of the respective rectangle structure. In other words, rectangular regions are defined and designated in the considered region; the indexing of the minimal boxes or image structures then corresponds to the respective rectangle index. As a simple example, the considered region is subdivided into four index rectangles and numbered from 1 to 4. The minimal boxes (or the image structures) then acquire as index the number of the rectangle in which they are situated. This indexing precedes the actual determination of the intersection structures. For the case where the index rectangles contain (likewise rectangular) minimal boxes, the indexing is possible with comparatively low computational complexity.

In this case, the combination of both measures, i.e. the definition of minimal boxes and the definition of index rectangles, is particularly advantageous, but not necessary. Accordingly, certain embodiments may include one measure, or the other, or both.

It is furthermore advantageous if the index rectangles for their part contain a plurality of index rectangles, likewise containing further index rectangles, minimal boxes or image structures. A multilevel indexing of the image structures or minimal boxes can be effected in this way. In this case, the indexing depth, i.e. the number of indices per minimal box or image structure, can indeed be different for different minimal boxes/image structures. By way of example, a minimal box may have an index M₁₂₃₄, which would mean that the box is situated
in the fourth index rectangle
of the third index rectangle
of the second index rectangle
of the first index rectangle.

It is likewise conceivable for a minimal box to be indexed as M₃₁, which means that the minimal box is situated in the first rectangle of the third rectangle. Depending on the complexity of the structures and in particular depending on the homogeneity or inhomogeneity of the image structures in the considered region, it may be advantageous to adapt the indexing depth regionally.

Following this indexing of the rectangles, minimal boxes or image structures, intersections with the rectangles can then be ascertained proceeding from each starting structure along the intersection line.

In cases in which the intersection line does not intersect the considered index rectangle, it also cannot intersect any of the minimal boxes or image structures therein and the content of this index rectangle need no longer be considered.

However, if the intersection line intersects the index rectangle, then the further content of this index rectangle (i.e. possibly further index rectangles, minimal boxes or image structures) is examined further. In certain embodiments, the method ends for each index rectangle as soon as all minimal boxes or image structures which are situated therein and which are intersected by the intersection line have been ascertained.

In this way, either
directly all image structures intersected by the respective intersection lines
or all minimal boxes intersected by the respective intersection lines can be determined.

In the second case, the minimal boxes are typically transformed back into image structures. In this case, for example, the rectangular contact box is replaced by the corresponding polygonal image structure. The intersection of the intersection line discussed above is then carried out once again for these image structures. In this case, minimal boxes whose associated image structure is not intersected can then also be omitted.

With the intersection points of the image structures obtained in this way, the further evaluation of the parameters respectively of interest can be carried out.

In this regard, for example, a distribution of distances of neighboring structures with respect to one another can be ascertained. From such a distribution, it is then possible to draw conclusions about the expected behavior of an examined structure, for example regarding possible fault currents on an electronic component produced using a photomask that has been examined according to embodiments of the method described.

Advantageously, the index rectangles are organized in a tree structure, in particular in an R-tree structure. Such structures are used for example in geo-databases for indexing multidimensional data. R-trees permit multidimensional search criteria and distance calculations, which can be used advantageously for the present requirements.

Sorted rows or hash tables are also appropriate, inter alia, as further possible index structures.

Other features, objects, and advantages follow.

### DESCRIPTION OF THE DRAWINGS

Exemplary embodiments and variants are explained in greater detail below with reference to the drawing, in which.

FIG. 1 shows a schematic illustration of the starting situation,

FIG. 2 shows for example a computation time as a function of the number of image structures to be considered,

FIG. 3 shows a first step of a method according to the invention,

FIG. 4 shows an example of the application of index rectangles,

FIG. 5 shows an example of determined intersections,

FIG. 6 shows a further step of the method according to the invention,

FIG. 7 shows an illustration concerning a variant of the method,

FIG. 8 shows a comparison of computation times according to the prior art and upon application of the method according to the invention.

### DETAILED DESCRIPTION

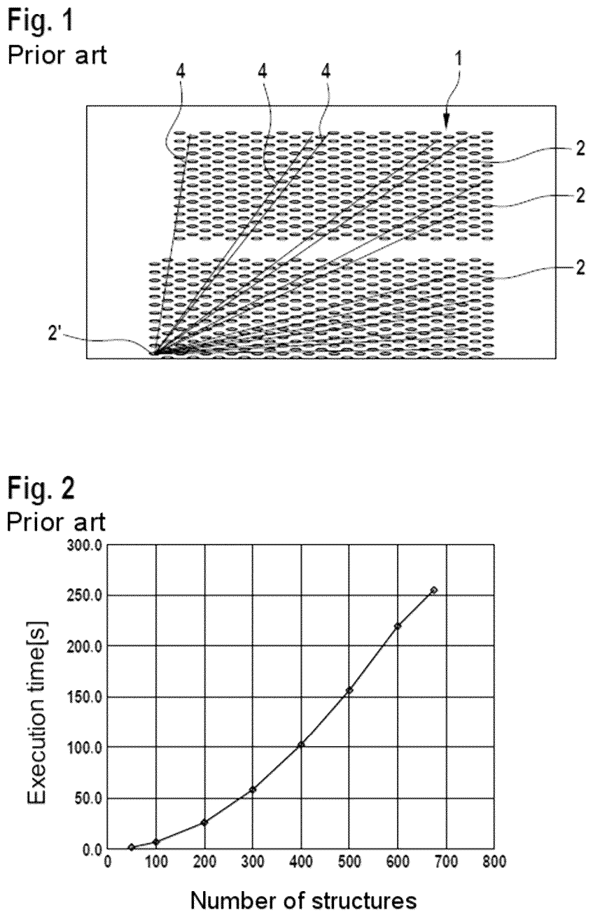

FIG. 1 shows a schematic illustration of the starting situation on the basis of a considered region 1 constituting an already processed excerpt from a recording from a mask inspection microscope. In the present case, a mask region with a multiplicity of contact holes was originally recorded, the contact holes being represented as image structures 2 in the figure. It is important precisely in the case of contact holes to ascertain mean distances of nearest neighbors in order to be able to estimate the risk of a current flow in a contact hole being undesirably influenced by a current flow in a neighboring contact hole between the individual contact holes. FIG. 1 illustrates by way of example one image structure as a starting structure 2′, from which a plurality of intersection lines 4 proceed. The intersection lines 4 intersect a multiplicity of image structures 2. For reasons of clarity, only a single starting structure 1 and a few exemplary intersection lines 4 are illustrated in FIG. 1. In the real case, a plurality of intersection lines 4 proceed from each of the image structures 2 shown in the figure. According to the prior art, for this purpose the boundaries of the image structures 2 are subdivided into a plurality of sections, from each of which an intersection line 4 proceeds perpendicularly. As the number of image structures 2 increases, this results in a high complexity of the required calculations, which is additionally increased by the fact that intersections with complex polygons are to be determined.

This increasing complexity is elucidated in FIG. 2. FIG. 2 shows the execution time for a corresponding computation as a function of the image structures contained in the respective region. The quadratic dependence of the execution time on the number of image structures is readily discernible in the figure.

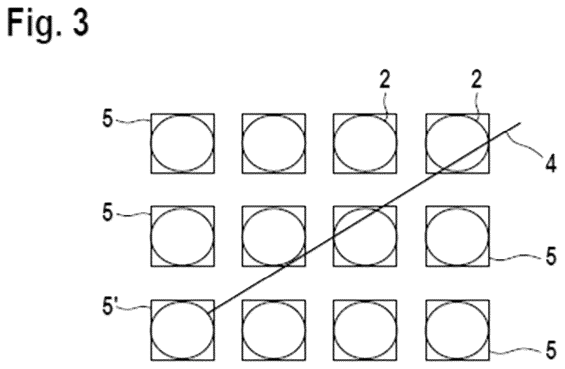

FIG. 3 illustrates a first step of a method according to the invention. The figure shows the creating of minimal boxes 5 from the original image structures 2. In this case, the minimal boxes 5 arise by virtue of the minimal boxes 5 being circumscribed as the smallest possible rectangles around the image structures 2 originally present. In this case, too, intersections of an intersection line 4 with surrounded structures 5 are determined proceeding from a starting structure 5′. The computation method for determining the intersections can already be considerably simplified by virtue of the fact that intersections with rectangles, namely the minimal boxes 5, are to be determined according to the invention, instead of the intersections with the original polygonal image structures 2.

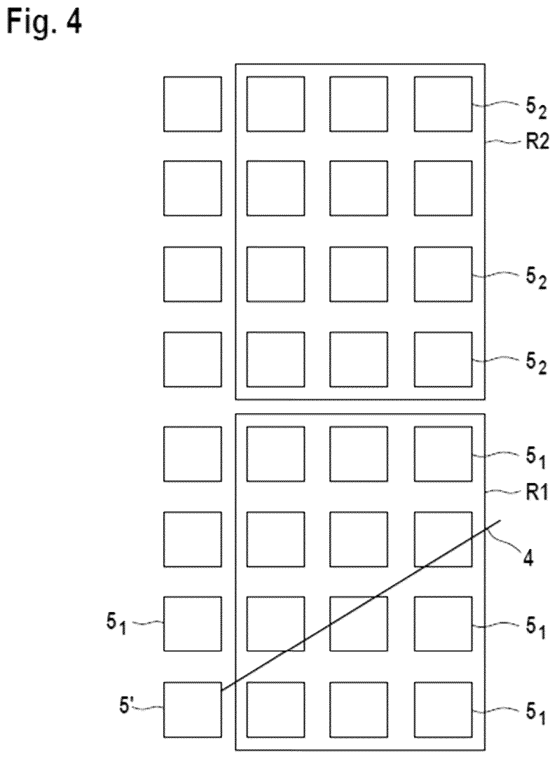

A further simplification results from the measure illustrated in a simplified manner in FIG. 4. There the considered region is subdivided into two index rectangles R1 and R2 containing the minimal boxes 5₁ and 5₂. Proceeding from the starting structure 5′, firstly intersections with the index rectangles R1 and R2 are determined along the intersection line 4. No intersection can be determined for the index rectangle R2. It is thus clear that it is not necessary to determine intersections with the minimal boxes 5₂. Intersections are determined, however, for the minimal boxes 5₁ in index rectangle R1.

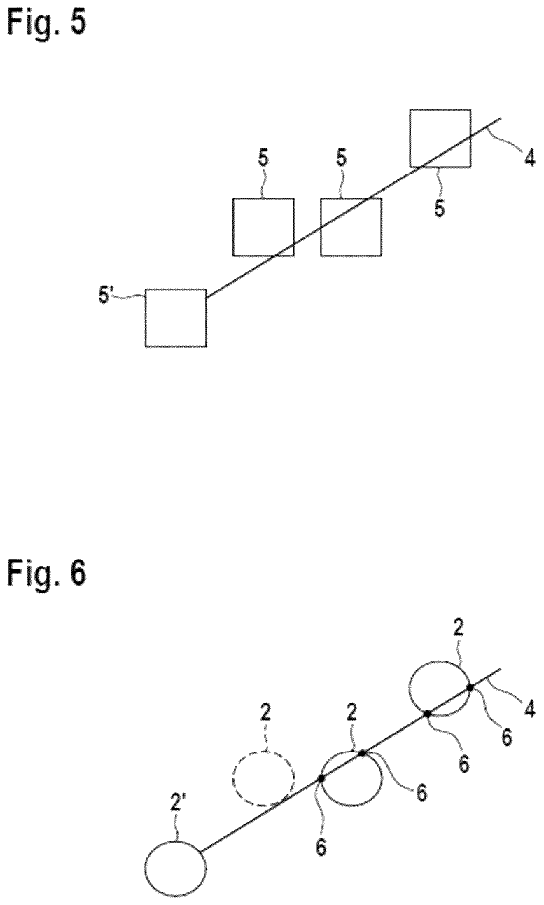

The result of this determination is illustrated in FIG. 5. FIG. 5 illustrates only the minimal boxes 5 that were intersected by the intersection line 4. They are the only boxes that contain candidates of image structures 2 which can be intersected by the intersection line 4. However, it is now still necessary to carry out a corresponding test for the remaining minimal boxes.

FIG. 6 shows the result of this test. The minimal boxes 5 were replaced by the associated image structures 2 and the intersection points 6 were determined. The figure reveals that the image structure 2 represented in a dashed manner is not intersected by the intersection line 4 even though its associated minimal box was intersected. With the result, namely the intersection points 6 ascertained, the method for determining distances can then be continued, as known from the prior art.

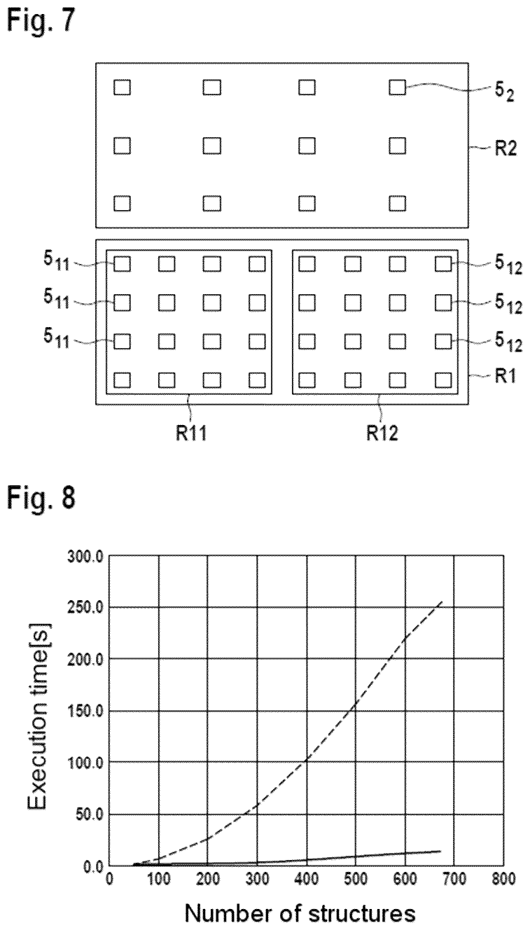

FIG. 7, in a simplified illustration, elucidates a variant of the method according to the invention which is suitable particularly for cases in which the density of the structures to be considered fluctuates greatly across the region of interest. In such cases, it may be advantageous to define index rectangles recursively with a different indexing depth, as elucidated in the figure by the index rectangles R1, R11 and R12. A recursive definition of index rectangles may also be advantageous for a uniform density of the structures to be considered. In this case, the indexing depth may be uniform over the entire considered region. The complexity of an R-tree that arises as a result, for example, and the associated computational complexity with the use of the R-tree should regularly be weighed up against the reduction of the computational complexity for determining the intersection points.

In principle, in certain embodiments, an application of the method, and in particular of the R-tree, is worthwhile primarily in those cases in which a multiplicity of structures should be expected not to be intersected by the slices, as is typically the case for a contact hole structure, for example. Such a scenario is also referred to as a “sparse” scenario. Conversely, in the case of a so-called lines and spaces structure, i.e. a structure comprising a multiplicity of usually parallel lines with interspaces, a multiplicity of intersections should also be expected (dense scenario).

It is therefore advantageous to take a decision about the application of the method using a corresponding prior estimation.

In particular, the prior estimation can comprise the determination of characteristic variables for estimating the proportion of intersected image structures in the total number of considered structures.

In this case, a quantitative estimation that is advantageous for this can be carried out as described below.

Firstly, the number of image structures n in the region to be considered and the number of slices s proceeding from an arbitrary but specific image structure are ascertained.

Furthermore, the number m of all intersections of all slices proceeding from the specific image structure with all other minimal boxes in the considered region is determined. It is to sufficient in this case only to ascertain the intersections with the minimal boxes, without carrying out the abovementioned test with the image structures, since all that matters is the order of magnitude of m.

From the values (natural numbers) ascertained in this way, it is then possible to determine parameters for the decision as to whether the application of the R-tree is advantageous:

$${d}_{sparse} = \vert 1 - \frac{m}{n} \vert$$

$${d}_{dense} = \vert 1 - \frac{m}{n * s} \vert$$

In this case, the characteristic variable dₛₚₐᵣₛₑ is a measure of the distance between the considered scenario and the sparse scenario already mentioned, i.e. that scenario in which the application of the R-tree would be worthwhile. Conversely, the characteristic variable d_{dense} is a measure of the distance between the considered scenario and the dense scenario, in which the application of the R-tree would not be worthwhile.

An application of the R-tree is worthwhile if either

$${d}_{sparse} < {d}_{dense}$$

$$or$$

$$m < n$$

The two scenarios already mentioned are compared by way of example below using realistic values:

| | n | s | m | dₛₚₐᵣₛₑ | d_{dense} |
|---|---|---|---|---|---|
| Contact holes | 1000 | 100 | 1500 | 0.5 | 0.985 |
| Lines and Spaces | 20 | 1000 | 10000 | 499 | 0.5 |

It becomes apparent that in the exemplary case, the application of the R-tree is only worthwhile for the scenario “Contact holes”.

FIG. 8 illustrates by way of example computation times for the method according to the prior art (dashed curve) and for the method according to the invention (solid curve) as a function of the number of considered structures. The approximately logarithmic profile of the computation time for the method according to the invention by comparison with an approximately quadratic profile according to the prior art is evident.

### Electronic Implementations

The subject matter and the actions and operations described in this specification can be implemented in digital electronic circuitry, in tangibly-embodied computer software or firmware, in computer hardware, including the structures disclosed in this specification and their structural equivalents, or in combinations of one or more of them. The subject matter and the actions and operations described in this specification can be implemented as or in one or more computer programs, e.g., one or more modules of computer program instructions, encoded on a computer program carrier, for execution by, or to control the operation of, data processing apparatus. The carrier can be a tangible non-transitory computer storage medium. Alternatively or in addition, the carrier can be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

The term “data processing apparatus” encompasses all kinds of apparatus, devices, and machines for processing data, including by way of example a programmable processor, a computer, or multiple processors or computers. Data processing apparatus can include special-purpose logic circuitry, e.g., an FPGA (field programmable gate array), an ASIC (application-specific integrated circuit), or a GPU (graphics processing unit). The apparatus can also include, in addition to hardware, code that creates an execution environment for computer programs, e.g., code that constitutes processor firmware, a protocol stack, a database management system, an operating system, or a combination of one or more of them.

A computer program can be written in any form of programming language, including compiled or interpreted languages, or declarative or procedural languages, and it can be deployed in any form, including as a stand-alone program, e.g., as an app, or as a software module, component, engine, subroutine, or other unit suitable for executing in a computing environment, which environment may include one or more computers interconnected by a data communication network in one or more locations.

A computer program may, but need not, correspond to a file in a file system. A computer program can be stored in a portion of a file that holds other programs or data, e.g., one or more scripts stored in a markup language document, in a single file dedicated to the program in question, or in multiple coordinated files, e.g., files that store one or more modules, sub-programs, or portions of code.

The processes and logic flows described in this specification can be performed by one or more computers executing one or more computer programs to perform operations by operating on input data and generating output. The processes and logic flows can also be performed by special-purpose logic circuitry, e.g., an FPGA, an ASIC, or a GPU, or by a combination of special-purpose logic circuitry and one or more programmed computers.

Computers suitable for the execution of a computer program can be based on general or special-purpose microprocessors or microcontrollers or a combination of them, or any other kind of central processing unit. Generally, a central processing unit will receive instructions and data from a read-only memory or a random access memory or both. The essential elements of a computer are a central processing unit for executing instructions and one or more memory devices for storing instructions and data. The central processing unit and the memory can be supplemented by, or incorporated in, special-purpose logic circuitry.

Generally, a computer will also include, or be operatively coupled to, one or more mass storage devices, and be configured to receive data from or transfer data to the mass storage devices. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

To provide for interaction with a user, the subject matter described in this specification can be implemented on one or more computers having, or configured to communicate with, a display device, e.g., a LCD (liquid crystal display) monitor, or a virtual-reality (VR) or augmented-reality (AR) display, for displaying information to the user, and an input device by which the user can provide input to the computer, e.g., a keyboard and a pointing device, e.g., a mouse, a trackball or touchpad. Other kinds of devices can be used to provide for interaction with a user as well, for example, feedback and responses provided to the user can be any form of sensory feedback, e.g., visual, auditory, speech, or tactile feedback or responses; and input from the user can be received in any form, including acoustic, speech, tactile, or eye tracking input, including touch motion or gestures, or kinetic motion or gestures or orientation motion or gestures. In addition, a computer can interact with a user by sending documents to and receiving documents from a device that is used by the user; for example, by sending web pages to a web browser on a user's device in response to requests received from the web browser, or by interacting with an app running on a user device, e.g., on a smartphone or electronic tablet. Also, a computer can interact with a user by sending text messages or other forms of message to a personal device, e.g., a smartphone that is running a messaging application, and receiving responsive messages from the user in return.

The term “configured to” may be used herein in connection with systems, apparatus, and computer program components. That a system of one or more computers is configured to perform particular operations or actions means that the system has installed on it software, firmware, hardware, or a combination of them that in operation cause the system to perform the operations or actions. That one or more computer programs is configured to perform particular operations or actions means that the one or more programs include instructions that, when executed by data processing apparatus, cause the apparatus to perform the operations or actions. That special-purpose logic circuitry is configured to perform particular operations or actions means that the circuitry has electronic logic that performs the operations or actions.

The subject matter described in this specification can be implemented in a computing system that includes a back-end component, e.g., as a data server, or that includes a middleware component, e.g., an application server, or that includes a front-end component, e.g., a client computer having a graphical user interface, a web browser, or an app through which a user can interact with an implementation of the subject matter described in this specification, or any combination of one or more such back-end, middleware, or front-end components. The components of the system can be interconnected by any form or medium of digital data communication, e.g., a communication network. Examples of communication networks include a local area network (LAN) and a wide area network (WAN), e.g., the Internet.

The computing system can include clients and servers. A client and server are generally remote from each other and typically interact through a communication network. The relationship of client and server arises by virtue of computer programs running on the respective computers and having a client-server relationship to each other. In some implementations, a server transmits data, e.g., an HTML page, to a user device, e.g., for purposes of displaying data to and receiving user input from a user interacting with the device, which acts as a client. Data generated at the user device, e.g., a result of the user interaction, can be received at the server from the device.

Other aspects, embodiments, and features are within the scope of the following claims.

### LIST OF REFERENCE SIGNS

1 Considered region
2,2′ Image structure, starting structure
4 Intersection line
5,5′ Minimal box, starting structure
6 Intersection point
R Rectangle structure

What is claimed is:

1. A method for examining samples pertaining to microlithography, comprising:
generating an aerial image of at least one considered region of the sample and generating image structures from the aerial image,
determining distances between a plurality of starting structures present in the aerial image and respective neighboring structures, determining the distances being effected by firstly determining intersection structures intersected by a predetermined intersection line proceeding from the respective starting structure,
wherein
rectangle structures are defined in the considered region for the determination of the intersection structures.

2. The method of claim 1,
wherein
rectangle structures are created by a respective rectangle structure containing exactly one image structure.

3. The method of claim 2,
wherein
the rectangle structures are created as minimal boxes by rectangles being circumscribed around image structures.

4. The method of claim 1,
wherein
rectangle structures are created as index rectangles by rectangular regions being defined in the considered region, which rectangular regions contain a plurality of minimal boxes or image structures indexed on the basis of the respective rectangle structure.

5. The method of claim 4,
wherein
index rectangles for their part contain a plurality of index rectangles.

6. The method of claim 4,
wherein
subsets of the minimal boxes or of the image structures are indexed with a different indexing depth.

7. The method of claim 4,
wherein
the index rectangles are organized in a tree structure.

8. The method of claim 7,
wherein
the tree structure is designed as an R-tree structure.

9. The method of claim 4,
wherein
a decision about the application of the method is taken using a prior estimation.

10. The method of claim 9,
wherein
the prior estimation comprises the determination of characteristic variables for estimating the proportion of intersected image structures in the total number of considered structures.

11. The method of claim 2,
wherein
rectangle structures are created as index rectangles by rectangular regions being defined in the considered region, which rectangular regions contain a plurality of minimal boxes or image structures indexed on the basis of the respective rectangle structure.

12. The method of claim 11,
wherein
index rectangles for their part contain a plurality of index rectangles.

13. The method of claim 11,
wherein
subsets of the minimal boxes or of the image structures are indexed with a different indexing depth.

14. The method of claim 11,
wherein
the index rectangles are organized in a tree structure.

15. The method of claim 11,
wherein
a decision about the application of the method is taken using a prior estimation.

16. The method of claim 15,
wherein
the prior estimation comprises the determination of characteristic variables for estimating the proportion of intersected image structures in the total number of considered structures.

17. The method of claim 3,
wherein
rectangle structures are created as index rectangles by rectangular regions being defined in the considered region, which rectangular regions contain a plurality of minimal boxes or image structures indexed on the basis of the respective rectangle structure.

18. The method of claim 17,
wherein
index rectangles for their part contain a plurality of index rectangles.

19. The method of claim 17,
wherein
subsets of the minimal boxes or of the image structures are indexed with a different indexing depth.

20. The method of claim 17,
wherein
the index rectangles are organized in a tree structure.
